(19) United States
(12) Patent Application Publication
(10) Pub. No.: US 2020/0258805 A1
(43) Pub. Date: Aug. 13, 2020

(54) ELECTRONIC COMPONENT MODULE PROVIDED WITH SUBSTRATE ON WHICH ELECTRONIC COMPONENTS ARE MOUNTED AND HEAT SINK AND MANUFACTURING METHOD OF THE SAME

(71) Applicant: DENSO CORPORATION, Kariya-city, Aichi-pref. (JP)

(72) Inventors: Tomohiro YOKOCHI, Kariya-city, Aichi-pref. (JP); Kenichiro HASEGAWA, Kariya-city, Aichi-pref. (JP); Hidetada KAJINO, Kariya-city, Aichi-pref. (JP); Yasunori KASAMA, Kariya-city, Aichi-pref. (JP)

(21) Appl. No.: 15/780,728

(22) PCT Filed: Dec. 1, 2016
(86) PCT No.: PCT/JP2016/085719

§ 371 Date: Jun. 1, 2018

(30) Foreign Application Priority Data
Dec. 2, 2015 (JP) 2015-235905

(51) Int. Cl. H01L 23/367; H01L 23/13; H01L 23/14; H01L 23/40; H01L 25/065; H01L 25/07; H05K 1/02; H05K 3/46

(52) U.S. Cl. CPC H01L 23/367; H01L 23/13; H01L 23/14; H01L 23/40; H01L 25/065; H01L 25/07; H05K 2203/063; H05K 1/0268; H05K 3/4611; H01L 2224/16225; H05K 2203/302; H05K 2201/0388; H05K 1/0203

(57) ABSTRACT

An electronic component module includes a substrate; a plurality of electronic components mounted on the substrate; and a heatsink fixed to the substrate.

The substrate includes first, second and third substrates. The electronic components include first components and second components, and the first substrate and the second substrate are arranged such that the surface of the first and second substrates mutually face each other.

The third substrate is disposed between the first substrate and the second substrate, whereby the first, second and third substrates are continuous. The heatsink includes a fixed portion fixed to at least one substrate among the first substrate, the second substrate and the third substrate, and a side portion located in a side area of a region sandwiched between the first substrate and the second substrate. The side portion is continuous with the fixed portion via a bend portion having a bent shape.

### CROSS REFERENCE TO RELATED APPLICATIONS

This application is a U.S. National Phase Application under 35 U.S.C. 371 of International Application No. PCT/JP2016/085719 filed on Dec. 1, 2016 and published in Japanese as WO 2017/094834 A1 on Jun. 8, 2017. This application is based on and claims the benefit of priority from Japanese Patent Application No. 2015-235905 filed on Dec. 2, 2015. The entire disclosures of all of the above applications are incorporated herein by reference.

### FIELD

The present disclosure relates to an electronic component module including a plurality of electronic components integrated thereto and a manufacturing method of the same.

### BACKGROUND

Japanese Patent Application Laid-Open Publication Number 2007-305674 discloses a component-included substrate in which electronic components are included in the substrate.

As a manufacturing method of the component-included substrate, a method is disclosed in which a plurality of sealing substrates are sequentially laminated for sealing surface-mounted substrates after manufacturing surface-mounted substrates on which electronic components are mounted.

### PATENT LITERATURE

PTL 1 Japanese Patent Application Laid-Open Publication Number 2007-30567 4.

According to the above-described manufacturing method of the component-included substrate, a manufacturing step of laminating the plurality of sealing substrates is required in addition to a manufacturing step of the surface-mounted substrates. Hence, the required manufacturing time becomes significantly longer than a case where conventional surface-mounted substrates are manufactured.

Moreover, component-included substrates require an improvement of heat radiation properties for integrated electronic components.

### SUMMARY

Hence it is desired to provide an electronic component module capable of shortening a manufacturing time and improving heat radiation properties compared to a conventional component-included substrate and the manufacturing method thereof.

A typical one example of an electronic component module is an electronic component module including a plurality of electronic components integrated therein. The electronic component module includes: a substrate; a plurality of electronic components mounted on a surface of the substrate; and a heatsink made of metal and fixed to the substrate. The substrate includes a first substrate, a second substrate and a third substrate; the plurality of electronic components includes one or more first components mounted on a surface of the first substrate, and one or more second components mounted on a surface of the second substrate; the first substrate and the second substrate are arranged such that the surface of the first substrate and the surface of the second substrate face each other; the third substrate is disposed between the first substrate and the second substrate, whereby the first substrate, the second substrate and the third substrate are continuous; the substrate includes a plurality of insulation substrates each having a film shape, the insulation substrates being laminated in the substrate; the third substrate is configured such that the number of laminates of the insulation substrates is smaller than that of the first substrate and the second substrate; a part of third substrate or whole third substrate has a bent shape; the heatsink includes a fixed portion fixed to at least one substrate among the first substrate, the second substrate and the third substrate, and a side portion located in a side area of a region sandwiched between the first substrate and the second substrate; and the side portion is continuous with the fixed portion via a bend portion having a bent shape.

This electronic component module is manufactured by bending the substrate and the heatsink after a plurality of electronic components are mounted on the surface of the first substrate and the second substrate. In other words, this electronic component module is manufactured by bending the surface-mounted substrate after manufacturing the surface-mounted substrate. Hence, compared to a case where a plurality of sealing substrates are laminated after manufacturing the surface-mounted substrate, manufacturing time can be shortened.

Further, this electronic component module is configured such that a part of heatsink is disposed in a side area of the region sandwiched between the first substrate and the second substrate. Hence, compared to a case where the heatsink is not disposed in a side area of the region sandwiched between the first substrate and the second substrate, heat radiation properties can be improved.

Moreover, according to another typical example of the electronic component module is a method for manufacturing an electronic component module including a plurality of electronic components integrated therein. The method includes: preparing a substrate to which a heatsink is fixed; mounting the plurality of electronic components on a surface of the substrate; and bending the substrate to which the electronic components are mounted and the heatsink.

The substrate to be prepared includes a plurality of insulation substrates each having a film shape, the insulation substrates being laminated in the substrate, and includes a first substrate, a second substrate and a third substrate being continuous with both of the first substrate and the second substrate; the third substrate is configured such that the number of laminates of the insulation substrates is smaller than that of the first substrate and the second substrate; the heatsink fixed to the substrate includes a fixed portion and a side portion, the fixed portion being overlapped with at least one of the first substrate, the second substrate and the third substrate and fixed thereto, the side portion being continuous with the fixed portion and not being overlapped with any of the first substrate, the second substrate and the third substrate; a step of mounting includes a step of mounting one or more first component on a surface of the first substrate, and a step of mounting one or more second component on a surface of the second substrate; and a step of bending includes a step of disposing the first substrate and the second substrate by bending a part of the third substrate or whole third substrate of the substrate such that the one surface of the first substrate and the one surface of the second substrate face each other to constitute the third substrate being continuous between the first substrate and the second substrate, and a step of bending the side portion to have the side portion positioned in a side area of a region sandwiched between the first substrate and the second substrate.

According to the method for manufacturing the electronic component module, the surface-mounted substrate is bent after manufacturing the surface-mounted substrate. Hence, compared to a case where a plurality of sealing substrates are laminated after manufacturing the surface-mounted substrate, manufacturing time can be shortened.

Further, according to the method for manufacturing the electronic component module, the heatsink is bent, thereby disposing a part of the heatsink to be in a side area of the region sandwiched between the first substrate and the second substrate. Hence, compared to a case where the heatsink is not disposed in a side area of the region sandwiched between the first substrate and the second substrate, heat radiation properties can be improved.

Note that reference numbers in respective means disclosed in this section and claims are examples showing a correspondence with specific means described in the embodiments which will be described later.

### DRAWINGS

In the accompanying drawings:

FIG. 1 is a plan view showing an electronic component module according to a first embodiment;

FIG. 2 is a cross-sectional view of the electronic component module sectioned along II-II line shown in FIG. 1;

FIG. 3 is a side view showing the electronic component module shown in FIG. 1;

FIG. 4 is a flow chart showing a manufacturing process of the electronic component module according to the first embodiment;

FIG. 5 is a plan view of a mounting substrate showing a part of the manufacturing process of the electronic component module according to the first embodiment;

FIG. 6 is a cross-sectional view of the mounting substrate sectioned along VI-VI line shown in FIG. 5;

FIG. 7 is a plan view of a heat sink according to the first embodiment;

FIG. 8 is a plan view showing a printed wiring board according to the first embodiment;

FIG. 9 is a cross-sectional view showing the printed wiring board according to the first embodiment;

FIG. 10 is a cross-sectional view of a laminate showing a part of the manufacturing process of the electronic component module according to the first embodiment;

FIG. 11 is a cross-sectional view of an electronic component module according to a second embodiment;

FIG. 12 is a cross-sectional view of an electronic component module according to a third embodiment;

FIG. 13 is a cross-sectional view of an electronic component module according to a fourth embodiment;

FIG. 14 is a plan view of a mounting substrate showing a part of manufacturing process of the electronic component module according to the fourth embodiment;

FIG. 15 is a plan view of an electronic component module according to a fifth embodiment; and

FIG. 16 is a plan view of a mounting substrate showing a part of manufacturing process of the electronic component module according to the fifth embodiment.

### DESCRIPTION

With reference to the drawings, embodiments of the present disclosure will be described. In the embodiments, the same reference numbers are added to mutually identical or equivalent portions.

### First Embodiment

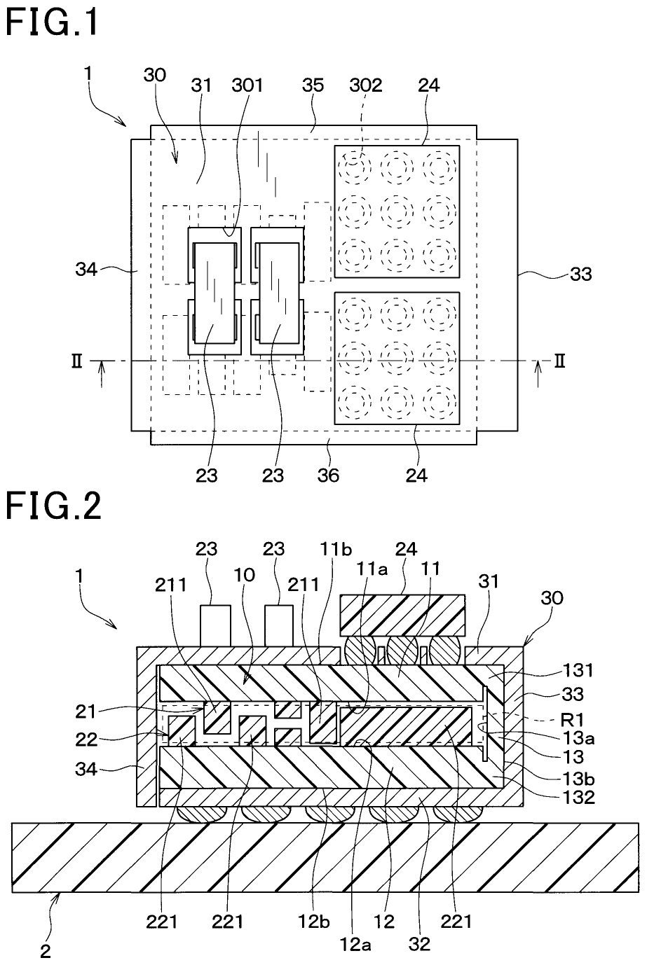

As shown in FIGS. 1 to 3, an electronic component module 1 according to the first embodiment includes a plurality of electronic components. The electronic component module 1 is mounted to a mother board 2 in a state where the electronic components are integrated to the electronic component module 1. The electronic component module 1 accomplishes a component-included substrate in which a plurality of electronic components are spuriously integrated.

Specifically, as shown in FIG. 2, the electronic component module 1 is provided with a printed wiring board 10, a plurality of electronic components 21, 22, 23 and 24, and a heatsink 30.

The printed wiring board 10 includes a first substrate 11, a second substrate 12 and a third substrate 13.

The first substrate 11 and the second substrate 12 are formed to have a plate shape. The third substrate 13 is continuous with both of the first substrate 11 and the second substrate 12. A portion 131 in the first substrate 11 side of the third substrate 13 and a portion 132 in the second substrate side 12 of the second substrate 132 form a bend portion having a bent shape. According to the present embodiment, the portion 131 in the first substrate 11 side of the third substrate 13 and the portion 132 in the second substrate 12 side are each bent at a right angle. A portion between the portion 131 in the first substrate 11 side of the third substrate 13 and the portion 132 in the second substrate 12 side is formed in a plate shape.

The thickness of the third substrate 13 is smaller than that of the first substrate 11 and the second substrate 12. Thus, the third substrate 13 is more flexible than the first substrate 11 and the second substrate 12. Each of the thicknesses of the first substrate 11 and the second substrate 12 is larger than that of the third substrate 13. Hence, the first substrate 11 and the second substrate 12 are configured to be harder than the third substrate 13.

The plurality of electronic components includes a plurality of first components 21 mounted on a surface 11a of the first substrate 11, and a plurality of second components 22 mounted on a surface 12a of the second substrate 12.

The first substrate 11 and the second substrate 12 are arranged such that the surface 11a and the surface 12a face each other, on which the first components and the second components are mounted thereon respectively. The plate shape of the first substrate 11 and the plate shape of the second substrate are the same rectangular.

A component 211 having the highest dimension among the first components 21 and a component 221 having the highest dimension among the second components 22 are arranged alternately in a direction parallel to the surface 11a of the first substrate 11 to be at mutually different positions.

The heatsink 30 includes a fixed portion fixed to the first substrate 11, the second substrate 12 and the third substrate 13, and a side portion located in the side of a region R1 between the first substrate 11 and the second substrate 12. The fixed portion is overlapped with the first substrate 11, the second substrate 12, and the third substrate 13. The side portion is not overlapped with any of the first substrate 11, the second substrate 12, and the third substrate 13. Note that the side of the region R1 refers to a side area with respect to a direction along which the first substrate 11 and the second substrate 12 are arranged. That is, the side of the region R1 is defined as an area extending in a horizontal direction when the direction along which the first substrate 11 and the second substrate 12 are arranged is defined as a vertical direction. In other words, the side of the region R1 is an area extending in a direction crossing the direction along which the first substrate 11 and the second substrate 12 are arranged. Note that “located in the side of the region R1” refers to that “located around a part of the region R1 which is not surrounded by the first substrate 11 and the second substrate 12.

The fixed portion includes a first fixed portion 31, a second fixed portion 32 and a third fixed portion 33. The first fixed portion is fixed to the other surface 11b which is opposite side of the surface 11a of the first substrate 11. The second fixed portion 32 is fixed to the other surface 12b which is opposite side of the surface 12a of the second substrate 12. The third fixed portion 33 is fixed to the other surface 13b which is opposite side of the surface 13a of the third substrate 13. Each of the plate shape corresponding to the first fixed portion 31, the second fixed portion 32, and the third fixed portion 33 is a rectangular shape which is the same as each plate shape corresponding to the first substrate 11, the second substrate 12 and the third substrate 13. As shown in FIG. 1, the third fixed portion 33 is continuous with a side of the first fixed portion 31.

As shown in FIG. 1, the side portion includes a first side portion 34, a second side portion 35 and a third side portion 36 which extend from respective other three sides of the first fixed portion 31. As shown in FIG. 2, the first side portion 34 serves as a bend portion having a shape in which a part of the first fixed portion 31 side is bent. The first side portion 34 has a plate shape in the portion excluding the bend portion. The second side portion 35 and the third side portion 36 have the same shape as the first side portion 34.

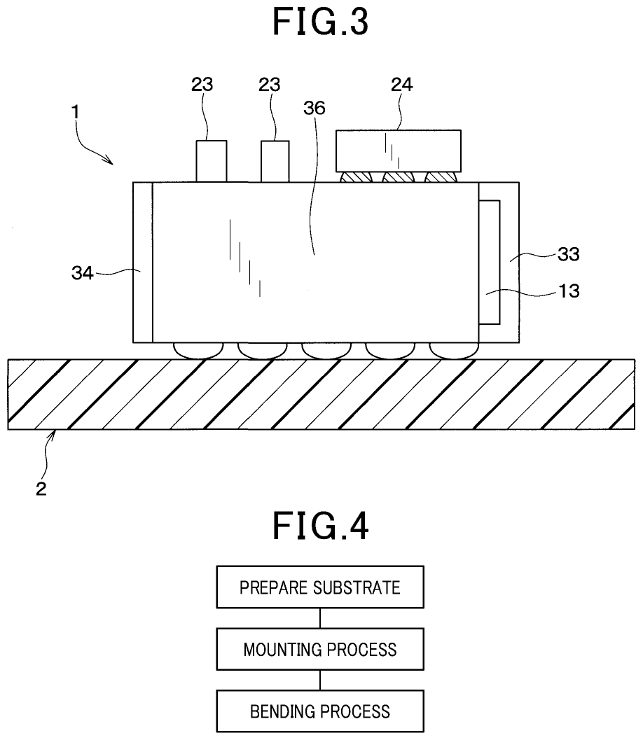

As shown in FIG. 3, the third side portion 36 is located in a side surface of the electronic component module 1. Similar to the third side portion 36, the first side portion 34 and the second side portion 35 are located in the side surface of the electronic component module 1.

In other words, as shown in FIG. 2, the first side portion 34 is located in a side portion of the region R1 and a side portion of the second substrate 12, where the region R1 is located between the first substrate 11 having the first component 21 mounted thereto and the second substrate 12 having second component mounted thereto. The first side portion 34 may be located at least in a side area of the region R1. Hence, the length of the first side portion 34 in a direction along which the first substrate 11 is opposed to the second substrate 12 (i.e., vertical direction in FIG. 2) may be longer than or equal to a length of an interval between the first substrate 11 and the second substrate 12 in the direction along which the first substrate 11 is opposed to the second substrate 12. Similar to the first side portion 34, the second side portion 35 and the third side portion 36 are located in the side area of the region R1.

With respect to the region R1, the first fixed portion 31 and the second fixed portion 32 in the heatsink 30 are disposed in the both sides relative to the direction along which the first substrate and the second substrate are arranged. In the heatsink 30, the first side portion 34, the second side portion 35, the third side portion 36 and the third fixed portion 33 are arranged to cover the entire area of the region R1. Hence, the heatsink 30 surrounds the region R1 from six directions.

The heatsink 30 is made of metal. In each of the first side portion 34, the second side portion 35 and the third side portion 36, entire metal surface is exposed. The heatsink 30 is electrically connected to the ground electrode (not shown) of the printed wiring board 10. Thus, the heatsink 30 has the ground potential.

A plurality of electronic components includes electronic components 23 and 24 mounted on the other surface 11b which is opposite to the surface 11a of the first substrate 11.

Next, a manufacturing method of the electronic component module 1 according to the present embodiment will be described.

As shown in FIG. 4, the manufacturing method of the electronic component module 1 includes a preparing process of substrate, a mounting process in which a plurality of electronic components are mounted on the substrates, and a bending process in which the mounted board is bent. These processes are sequentially executed.

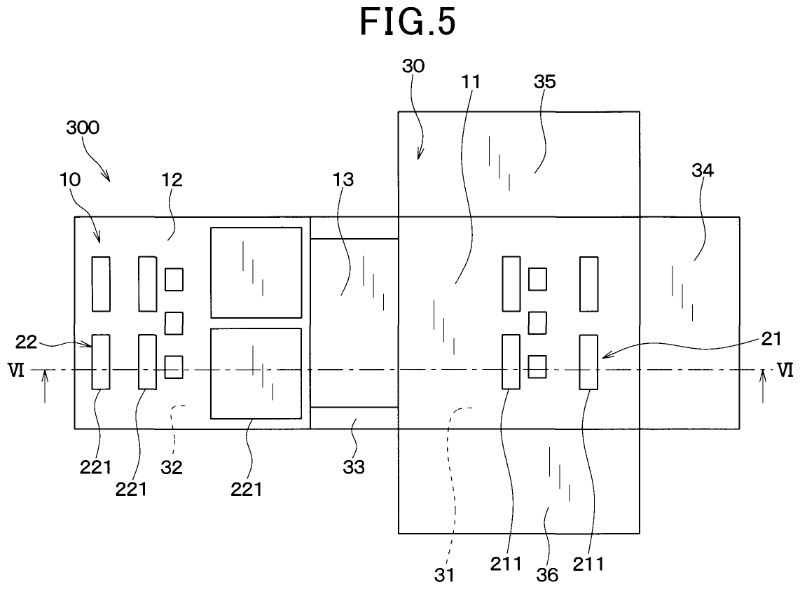

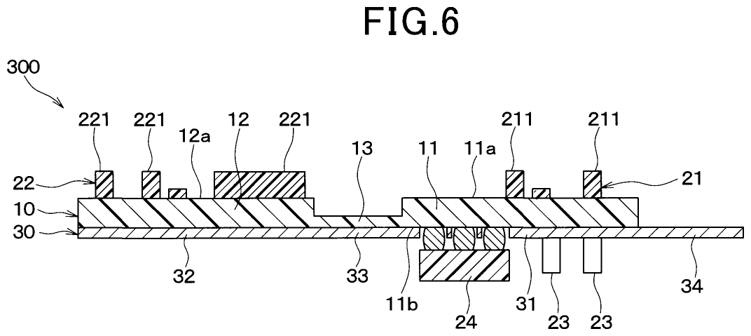

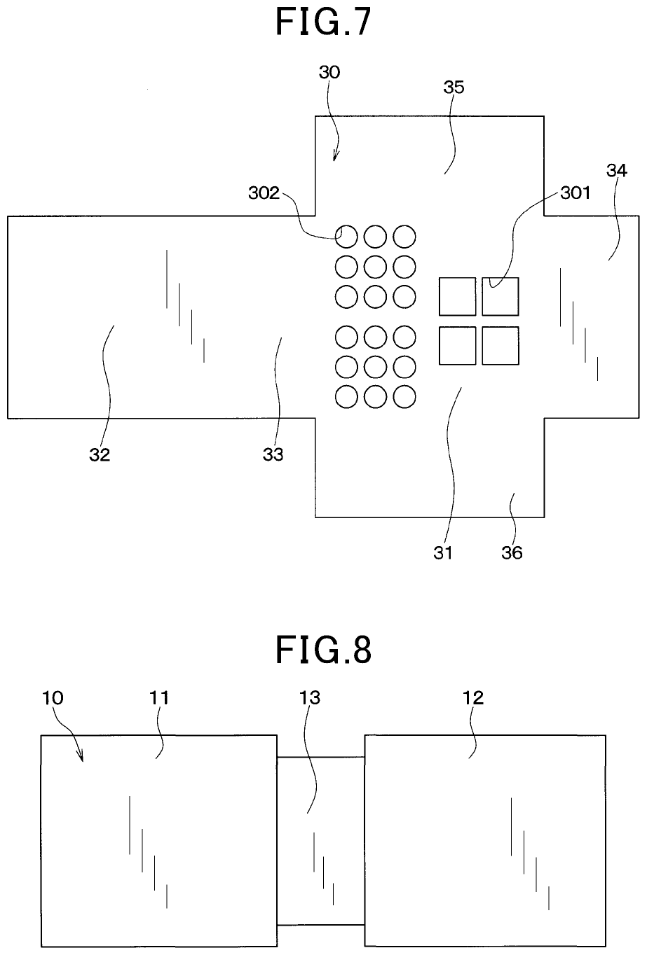

In the preparing process, as shown in FIGS. 5 and 6, the printed wiring board 10 to which the heatsink 30 is fixed is prepared. The printed wiring board 10 provided with the heatsink 30 fixed thereto is composed of a heatsink having plate shape shown in FIG. 7 and a printed wiring board 10 having plate shape shown in FIG. 8 which are fixed to each other. The heatsink 30 has an area of the shape larger than that of the printed wiring board 10. The heatsink 30 is fixed to the printed wiring board 10 in a state where the side portions 34, 35 and 36 are not overlapped with the printed wiring board 10. The heatsink 30 is constituted by a metal film such as copper film. The thickness of the heatsink 30 is set to be larger than that of a conductor pattern 102 which will be described later.

As shown in FIG. 7, the heatsink 30 has openings 301 and 302 used for mounting the electronic components 23 and 24.

As shown in FIG. 8, the printed wiring board 10 includes a first substrate 11, a second substrate 12 and a third substrate 13 (before bending process).

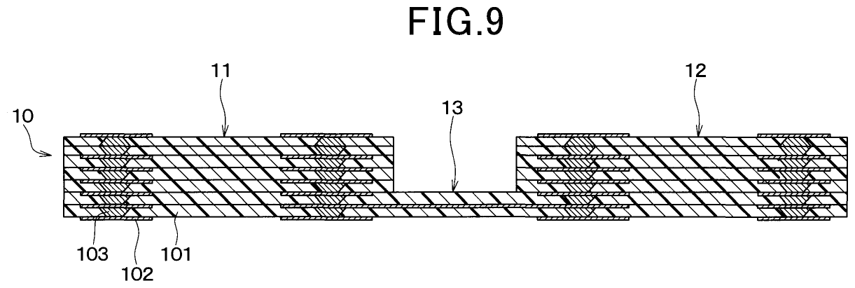

FIG. 9 is a specific cross-sectional view of the printed wiring board 10 shown in FIG. 8. As shown in FIG. 9, the printed wiring board 10 is formed such that a plurality of insulation substrates 101 each having a film shape are laminated. Each of the insulation substrates 101 has one or more conductor patterns 102 formed on the surface thereof. Each conductor pattern 102 is constituted by a metal film such as copper film. Each insulation substrate 101 includes one or more vias 103 formed in the thickness direction. The conductor patterns 102 and the vias 103 constitute a conductor wiring. The insulation substrate 101 is made of thermoplastic resin. Each insulation substrate 101 may be made of resin material other than the thermosetting resin. The insulation substrate 101 is not necessarily formed of a resin material, but may contain materials other than resin.

The third substrate 13 is configure such that the number of laminates of the insulation substrates 101 is smaller than that of the first substrate 11 and the second substrate 12. Thus, the thickness of the third substrate 13 is smaller than that of the first substrate 11 and the second substrate 12.

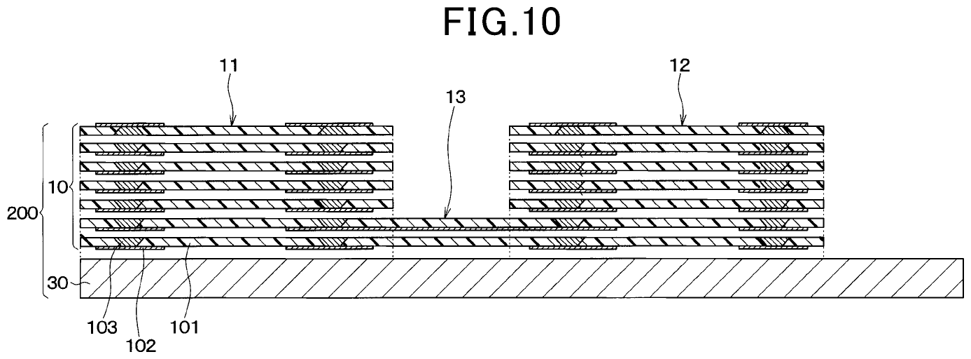

As shown in FIG. 10, a plurality of insulation substrates 101 including the conductor pattern 102 and the vias 103 and the heatsink 30 are laminated to form a laminate 200. Then the laminate 200 is heated and pressed. Thus, the plurality of insulation substrates are bonded, thereby forming the printed wiring board 10. Further, as shown in FIGS. 5 and 6, the heatsink 30 is bonded to the surface of the printed wiring board 10.

In the mounting process, as shown in FIGS. 5 and 6, a plurality of electronic components 21, 22, 23 and 24 are mounted on the surfaces 11a, 12a, 11b of the printed wiring board 10. Thus, a surface mounted substrate 300 is produced in which a plurality of electronic components 21, 22, 23 and 24 are mounted on the printed wiring board 10.

In the bending process, the surface-mounted substrate 300 shown in FIGS. 5 and 6 are bent to obtain the shape shown in FIGS. 1 to 3. Specifically, the third substrate 13 is bent together with the third fixed portion 33. Thereafter, the first side portion 34, the second side portion 35, and the third side portion 36 of the heatsink are bent. The third substrate 13 may be bent after the side portions 34, 35 and 36 are bent. After bending the heatsink 30, the first side portion 34, the second side portion 35 and the third side portion 36 are bonded to the side surface of the second substrate 12.

Thus, the electronic component module 1 according to the present embodiment is produced. Then, the electronic component module 1 is soldered with soldering balls or the like and mounted to the mother board 2.

Next, effects of the present embodiment will be described.

(1) The electronic component module 1 according to the electronic component module 1 is produced by bending the third substrate 13 and the side portions 34, 35 and 36 after the plurality of electronic components 21 and 22 are mounted to the surfaces 11a and 12a of the first substrate 11 and the second substrate 12. In other words, the electronic component module 1 is produced by bending the surface-mounted substrate 200 after manufacturing the surface-mounted substrate 300. Hence, compared to a case where a plurality of sealing substrates are laminated after manufacturing the surface-mounted substrate, the manufacturing time can be shortened.

(2) In the electronic component module 1 according to the present embodiment, a part of the heatsink 30 is disposed around the region R1 between the first substrate 11 and the second substrate 12. Thus, compared to a case where the heatsink 30 is not disposed around the region R1, heat radiation properties can be improved. In particular, according to the present embodiment, the first side portion 34, the second side portion 35 and the third side portion 36 are arranged in the entire region excluding the third substrate 13 in the side area of the region R1. In other words, a part of the heatsink is arranged in the entire region around the region R1 by the first side region 34, the second side region 35, the third side region 36 and the third fixed region 33. Thus, compared to a case where the heatsink is disposed in a part of the periphery of the region R1, the heat radiation properties can be improved.

(3) Unlike the electronic component module 1 of the present embodiment, when the side portions 34, 35 and 36 are constituted separately from the fixed portions 31, 32 and 33, another process is required in which the side portions 34, 35 and 36 are attached to the surface-mounted substrate 300 being bent. In this case, positional alignment is required for the side portions 34, 35 and 36 with respect to the surface-mounted substrate 300.

According to the electronic component module 1, the side portions 34, 35 and 36 are continuous with the fixed portions 31, 32 and 33. The side portions 34, 35 and 36 are bent, thereby being arranged around the region R1. Thus, when manufacturing the electronic component module 1, a process for attaching the side portions 34, 35 and 36 is not required. Hence, compared to a case where the side portions 34, 35 and 26 are constituted separately from the fixed portions 31, 32 and 33, manufacturing time can be shortened.

(4) According to the electronic component module 1, the heatsink 30 has the ground potential. Thus, the heatsink 30 can serve as an electromagnetic shield. That is, the first fixed portion 31, the second fixed portion 32, the third fixed portion 33, the first side portions 34, the second side portion 35 and the third portion 36 can cutoff electromagnetic waves emitted towards the first component 21 and the second component 22 from outside. Accordingly, reliability of electronic components in the electronic component module is improved.

(5) The electronic component module 1 is disposed such that the electronic components 211 and 221 are arranged to be at different positions in a direction parallel to the surface 11a of the first substrate 11a. Thus, the height of the electronic component module 1 can be lowered. As a result, the electronic component can be smaller.

(6) According to the manufacturing method of the electronic component module 1, the first component 21 and the second component 22 can be inspected and repaired even after the mounting process and before the bending process.

### Second Embodiment

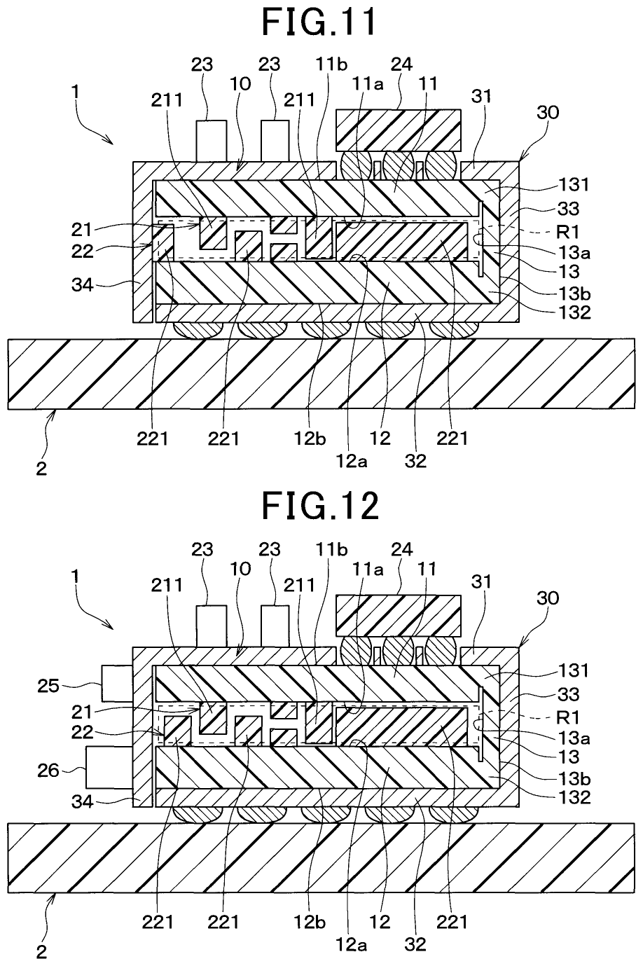

As shown in FIG. 11, the electronic component module 1 is different from that of the first embodiment such that the first side portion 34 of the heatsink 30 contacts with the second component 22 which is an electronic component of a heat radiation object. Other configurations of the electronic component module 1 is the same the electronic component module 1 of the first embodiment.

The contact surface of the second component 22 of the first side portion 34 is made of metal. The first side portion 34 is fixed to the second component 22 by an adhesive such as metal paste coated on the periphery of the contact surface of the second component 22.

The manufacturing method of the electronic component module 1 according to the present embodiment is different from that of the first embodiment as follows. An arrangement of the second component 22 in the mounting process is changed. In the bending process, when the first side portion 34 is bent, the first side portion 34 contacts with the second component 22. Thereafter, the first side portion 34 is bonded with the second component 22.

The electronic component module 1 according to the second embodiment contacts the second component 22. Thus, the heat radiation properties of the second component 22 can be improved compared to a case where the first side portion 34 does not contact the second component 22.

According to the present embodiment, the first side portion 34 contacts the second component 22, but this is not limited thereto. For example, any one of side portions among the first side portion 34, the second side portion 35 and the third side portion 36 may contact at least one electronic component among one or more first component 21 and one or more second component 22.

### Third Embodiment

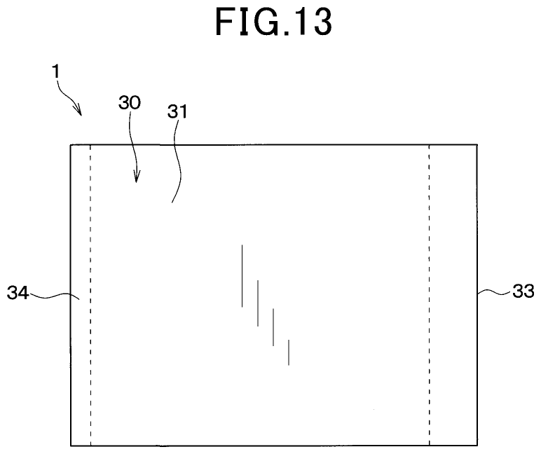

As shown in FIG. 12, the electronic component module 1 of the present embodiment differs from the electronic component module 1 of the first embodiment in that a plurality of electronic components 25 and 26 are mounted on the surface of the first side portion 34 of the heatsink 30. Other configurations of the electronic component module 1 are the same as those of the electronic component module 1.

Thus, the plurality of electronic components 25 and 26 can be mounted on the first side portion 34 as well. Note that the plurality of electronic components 25 and 26 may be mounted on the side portions 35 and 36 other than the first side portion 34.

### Fourth Embodiment

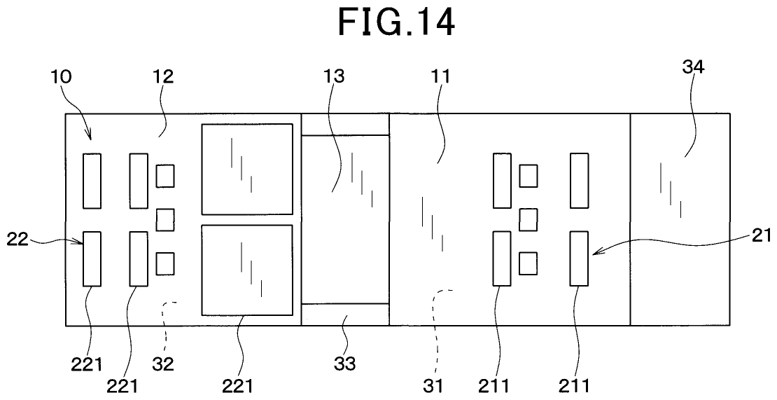

As shown in FIGS. 13 and 14, the electronic component module 1 of the present embodiment 1 differs from the electronic component module 1 of the first embodiment in that the second side portion 35 and the third side portion 36 of the heatsink 30 are not present. Other configurations of the electronic component module 1 are the same as those of the electronic component module 1 in the first embodiment. Note that illustration of the plurality of the electronic components is omitted in FIG. 13.

According to the present embodiment, only the first side portion 34 is located in the side area of the region R1. Thus, a side portion of the heatsink 30 may be located in a part of a side area of the region R1, but not in the entire area excluding the third substrate 13 of the region R1. According to the present embodiment, the heat radiation properties of the side portion can be improved, compared to a case where the side portion of the heatsink 30 is not present in a side area of the region R1.

### Fifth Embodiment

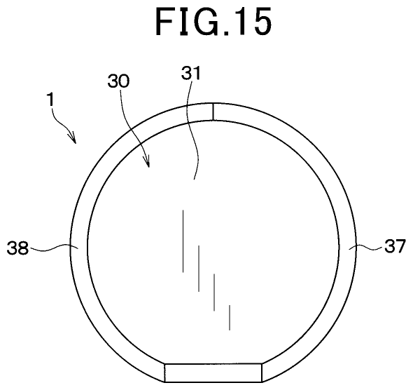

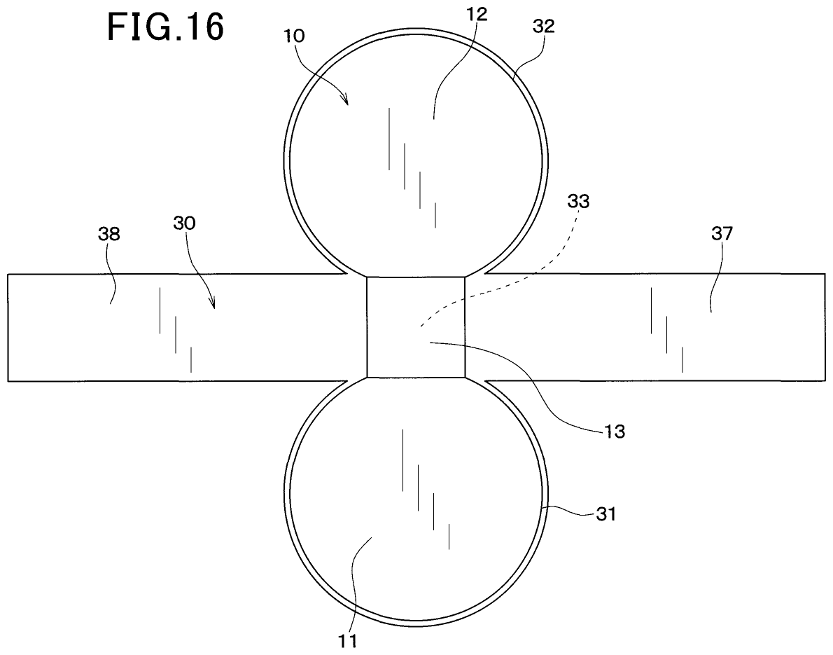

As shown in FIGS. 15 and 16, the electronic component module 1 according to the present embodiment differs from the electronic component module 1 of the first embodiment in that the plate shape is circular. Other configurations are the same as those of the electronic component module 1 of the first embodiment. Note that illustration of the plurality of the electronic components is omitted in FIGS. 15 and 16.

As shown in FIG. 16, the plate shape of the first substrate 11 and the second substrate 12 of the printed wiring board 10 is circular. Also, the plate shape of the first fixed portion 31 and the second fixed portion 32 of the heatsink is circular. The heatsink 30 has side portions 37 and 38.

As shown in FIGS. 15 and 16, the heatsink 30 of the present embodiment has a circular shape in which the fixed portion 33, the side portions 37 and 38 are bent. The first substrate 11 and the second substrate 12 constitute the bottom surface of the cylinder. The side portions 37 and 38 constitute the side portion of the cylinder. According to the present embodiment, the side portions 37 and 38 are located in the periphery of a region between the first substrate 11 and the second substrate 12. Hence, similar effects to the first embodiment can be obtained.

### OTHER EMBODIMENTS

The present disclosure is not limited to the above-described embodiment. However, the present disclosure can be appropriately modified in various manners within the scope of the claims.

(1) According to the first to third embodiments, each of the first side portion 34, the second side portion 35 and the third side portion 36 are continuous with the first fixed portion 31, but may be continuous with the second fixed portion 32. Moreover, it is not limited to the case where each of the first side portion 34, the second side portion 35 and the third side portion 36 are continuous with either the first fixed portion or the second fixed portion. For example, each of the first side portion 34, the second side portion 35 and the third side portion 36 may be continuous with the both of the first fixed portion 31 and the second fixed portion 32. In this case, for example, the first side portion 34 is divided into a part being continuous with the first fixed portion 31 and the second fixed portion 32.

(2) According to the above-described embodiments, the side portions 34, 35 and 36 are configured such that the metal surface is exposed to the entire area of the side portion. However, it is not limited to this configuration. The side portions 34, 35 and 36 may be configured such that each metal surface is covered with an insulation layer such as resin at a portion that requires insulation.

(3) According to the above-described embodiments, portions 131 and 132 as a part of the third substrate 13 have a bent shape. However, it is not limited this configuration. For example, whole substrate 13 may be configured to have a bent shape.

(4) According to the above-described embodiments, the heatsink 30 is fixed to the surface of the printed wiring board 10. However, it is not limited to this configuration. For example, the printed wiring board 10 may be fixed inside the printed wiring board 10. That is, the heatsink 30 may be bonded with the printed wiring board 10 in a state where the heatsink 30 is sandwiched between the insulation substrate 101 and the insulation substrate 101 which constitute the printed wiring board 10.

(5) The above-described embodiments can be appropriately combined except where elements have no mutual connection or combination thereof is impossible. Also, in each of the above-described embodiments, some elements which constitute the embodiment are not necessary except where the elements are clearly indicated as necessary and elements are theoretically necessary.

(Summary)

As a first aspect disclosed in a part or all of the above-described embodiments, the electronic component module is provided with a substrate, a plurality of electronic components and a heatsink. The substrate includes a first substrate, a second substrate and a third substrate. The first substrate and the second substrate are arranged such that a surface of the first substrate and a surface of the second substrate are faced with each other. The first substrate, the third substrate and the second substrate are continuous with each other. The heatsink includes a fixed portion which is fixed to at least one substrates among the first substrate, the second substrate and the third substrate, and a side portion located in a side area of a region sandwiched between the first substrate and the second substrate. The side portion is continuous with the fixed portion via the bend portion having a bent shape.

As the second aspect, the side portion contact with at least one electronic component among the first component and the second component. Thus, the heat radiation properties of the electronic components can be improved.

As the third aspect, the heatsink has the ground potential. Thus, the heatsink serves as electromagnetic shield. In other words, electromagnetic waves emitted toward the plurality of electronic components from the heatsink can be cutoff by the heat sink.

As the fourth aspect, the fixed portion are fixed to the first substrate, the second substrate and the third substrate. The side portion is arranged in the entire area excluding the third substrate in the side area of the region sandwiched by the first substrate and the second substrate. Thus, the heat radiation properties can be improved.

As the fifth aspect, a manufacturing method of the electronic component module includes a step of preparing a substrate to which the heatsink is fixed, a step of mounting a plurality of electronic components on a surface of the substrate, and a step of bending the mounted substrate and the heatsink. The bending step includes a step of disposing the first substrate and the second substrate by bending the substrate such that the one surface of the first substrate and the one surface of the second substrate face each other to constitute the third substrate being continuous with between the first substrate and the second substrate. The bending step further includes a step of bending the side portion to have the side portion positioned in a side area of the region sandwiched between the first substrate and the second substrate.

As the sixth aspect, the side portion is positioned in a side area of the region to have the side portion contact with at least one component among the first component and the second component. Thus, the heat radiation properties can be further improved.

As the seventh aspect, during a step of preparing the substrate to which the heatsink is fixed, a substrate is prepared in which the heatsink is electrically connected to the ground electrode. Thus, electromagnetic waves emitted toward the plurality of electronic components from the heatsink can be cutoff. In other words, the heatsink serves as electromagnetic shield.

As the eighth aspect, during a step of preparing the substrate to which the heatsink is fixed, a substrate is prepared in which the fixed portion are overlapped with each of the first substrate, the second substrate and the third substrate. The side portion is positioned in a side area of the region such that the side portion is located in the entire area in the side area of the region excluding the third substrate. Thus, the heat radiation properties of the electronic component can be improved.

What is claimed is:

1. An electronic component module including a plurality of electronic components integrated therein, the electronic component module comprising:
a substrate;
a plurality of electronic components mounted on a surface of the substrate; and
a heatsink made of metal and fixed to the substrate, wherein
the substrate includes a first substrate, a second substrate and a third substrate;
the plurality of electronic components includes one or more first components mounted on a surface of the first substrate, and one or more second components mounted on a surface of the second substrate;
the first substrate and the second substrate are arranged such that the surface of the first substrate and the surface of the second substrate face each other;
the third substrate is disposed between the first substrate and the second substrate, whereby the first substrate, the second substrate and the third substrate are continuous;
the substrate includes a plurality of insulation substrates each having a film shape, the insulation substrates being laminated in the substrate;
the third substrate is configured such that the number of laminates of the insulation substrates is smaller than that of the first substrate and the second substrate;
a part of third substrate or whole third substrate has a bent shape;
the heatsink includes a fixed portion fixed to at least one substrate among the first substrate, the second substrate and the third substrate, and a side portion located in a side area of a region sandwiched between the first substrate and the second substrate; and
the side portion is continuous with the fixed portion via a bend portion having a bent shape.

2. The electronic component module according to claim 1, wherein
the side portion contacts at least one electronic component between the first component and the second component.

3. The electronic component module according to claim, wherein
the heatsink has a ground potential.

4. The electronic component module according to claim 1, wherein
the fixed portion is fixed to each of the first substrate, the second substrate an d the third substrate;
the side portion is arranged in an entire area excluding the third substrate in a side area of the region sandwiched by the first substrate and the second substrate.

5. A method for manufacturing an electronic component module including a plurality of electronic components integrated therein, the method comprising:
preparing a substrate to which a heatsink is fixed;
mounting the plurality of electronic components on a surface of the substrate; and
bending the substrate to which the electronic components are mounted and the heatsink, wherein
the substrate to be prepared includes a plurality of insulation substrates each having a film shape, the insulation substrates being laminated in the substrate, and includes a first substrate, a second substrate and a third substrate being continuous with both of the first substrate and the second substrate;
the third substrate is configured such that the number of laminates of the insulation substrates is smaller than that of the first substrate and the second substrate;
the heatsink fixed to the substrate includes a fixed portion and a side portion, the fixed portion being overlapped with at least one of the first substrate, the second substrate and the third substrate and fixed thereto, the side portion being continuous with the fixed portion and being overlapped with none of the first substrate, the second substrate and the third substrate;
a step of mounting includes a step of mounting one or more first component on a surface of the first substrate, and a step of mounting one or more second component on a surface of the second substrate; and
a step of bending includes a step of disposing the first substrate and the second substrate by bending a part of the third substrate or whole third substrate of the substrate such that the one surface of the first substrate and the one surface of the second substrate face each other to constitute the third substrate being continuous between the first substrate and the second substrate, and a step of bending the side portion to have the side portion positioned in a side area of a region sandwiched between the first substrate and the second substrate.

6. The method according to claim 5, wherein
the side portion is positioned in a side area of the region to have the side portion contact at least one component among the first component and the second component.

7. The method according to claim 5, wherein
during a step of preparing the substrate to which the heatsink is fixed, a substrate is prepared in which the heatsink is electrically connected to a ground electrode of the substrate.

8. The method according to claim 5, wherein
during a step of preparing the substrate to which the heatsink is fixed, a substrate is prepared in which the fixed portion are overlapped with each of the first substrate, the second substrate and the third substrate; and
the side portion is positioned in a side area of the region such that the side portion is located in an entire area in the side area of the region excluding the third substrate.
